(19) United States
(12) Patent Application Publication
(10) Pub. No.: US 2005/0280453 A1
(43) Pub. Date: Dec. 22, 2005

(54) Phase locked loop circuit

(75) Inventor: Yi-Bin Hsieh, Taipei (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: VIA Technologies Inc.

(21) Appl. No.: 11/086,541

(22) Filed: Mar. 22, 2005

(30) Foreign Application Priority Data
Jun. 18, 2004 (RW) 93117681

(51) Int. Cl. H03L 7/06

(52) U.S. Cl. 327/156

(57) ABSTRACT

A phase locked loop circuit includes a loop filter having a first input terminal and a second input terminal and including a first capacitor coupled to the first terminal; a resistor having one terminal coupled to the first input terminal; a second capacitor coupled to the second input terminal; and a source follower having an input terminal coupled to the second input terminal and an output terminal coupled the other terminal of the resistor; a first charge pump coupled to the first input terminal outputting a first current; and a second charge pump coupled to the second input terminal outputting a second current; wherein the first current is a multiple of the second current.

### BACKGROUND

The invention relates in general to a phase locked loop circuit. In particular, the invention relates to a phase locked loop circuit applied to transceivers and CD/DVD drivers.

FIG. 1 is a circuit diagram of a conventional phase locked loop circuit 1. The phase locked loop circuit 1 (hereinafter is referred to as PLL circuit) comprises a frequency divider 10, a phase detector 11, a charge pump 12, a loop filter 13, a voltage controlled oscillator 14, and a frequency divider 15. The frequency divider 10 divides the frequency of a clock signal REFCLK and outputs a reference signal of reference frequency F_{ref}. The phase detector 11 detects the phase difference between the clock signal of reference frequency F_{ref} and a feedback signal of feedback frequency F_{vce}_{_{—}}_{fb} and outputs up/down signals. The charge pump 12 outputs current I according to the up/down signals and thus changes its output voltage V_{C}, in conjunction with the loop filter 13. The voltage controlled oscillator (VCO) 14 outputs a controlled signal of frequency F_{vcol} corresponding to the voltage V_{C}. The frequency divider 15 receives the controlled signal and outputs the feedback signal of the feedback frequency F_{vco}_{_{—}}_{fb}. The loop filter 13 is in charge of filtering noises and transferring the output current I of the charge pump 12 to the voltage V_{C}.

For example, the loop filter 13 includes a network constituted of resistor R1 and capacitors C1 and C2. The transfer function (1) of the loop filter 13 is

$$\frac{{V}_{C}}{I} = \frac{S + \frac{1}{R1 \cdot C1}}{S \cdot C2 \cdot ( S + \frac{C1 + C2}{R1 \cdot C2 \cdot C1} )} \approx \frac{S + \frac{1}{R1 \cdot C1}}{S \cdot C2 \cdot ( S + \frac{1}{R1 \cdot C2} )} ; \qquad ( 1 )$$

wherein capacitance C1 is assumed to be far greater than capacitance C2, and I is the operating current of the charge pump 12. Generally, the loop filter 13 is required to have loop bandwidth far less than the reference frequency F_{ref}, and therefore the capacitance of the capacitor C1 will be very large, from several hundred pF to several thousand pF, also the capacitor C1 requires a large area of the layout.

FIG. 2 is a circuit diagram of another conventional PLL circuit 1′. The PLL circuit 1′ provides two charge pumps 120 and 121 to reduce the required layout area of capacitor. The charge pumps 120 and 121 respectively output operating currents I1 and I2, wherein I1 equals B×I2 and B is greater than 1. The transfer function (2) of the loop filter 13′ is

$$\frac{{V}_{C}}{I1} = \frac{S + \frac{1}{R1 \cdot B \cdot C3} + S \cdot \frac{C2}{B \cdot C3}}{S \cdot C2 ( S + \frac{1}{R1 \cdot C2} )} \approx \frac{S + \frac{1}{R1 \cdot B \cdot C3}}{S \cdot C2 ( S + \frac{1}{R1 \cdot C2} )} , \qquad ( 2 )$$

when capacitance C2 is far less than B×C3.

Comparing transfer functions (1) and (2), it is noted that the area of the capacitor C3 in FIG. 2 can be reduced to 1/ B times that of the capacitor C1 in FIG. 1. However, the capacitor C3 in FIG. 2 is a floating capacitor and therefore cannot be made using FET capacitors (field effect transistor capacitors) with more capacitance per unit area. Because the capacitor C3 in FIG. 2 only can be made using poly-to-poly capacitors with less capacitance per unit area, or metal-to-metal capacitors, reduction of the area of the capacitor C3 is still limited. In addition, the loop filter 130 in FIG. 2 further requires an operational amplifier 130 and an adder 131, and thus circuit complexity, circuit area, and circuit noises are all increased.

### SUMMARY

The invention is directed to a phase locked loop circuit with smaller circuit configuration and less layout area than conventional arts and capable of reducing noise.

According to one exemplary embodiment of the invention, the phase locked loop circuit comprises a loop filter with a first and second input terminals, a first charge pump coupled to the first input terminal outputting a first current, and a second charge pump coupled to the second input terminal outputting a second current; wherein the first current is a multiple of the second current.

The loop filter further comprises a first capacitor coupled to the first terminal, a resistor having one terminal coupled to the first input terminal, a second capacitor coupled to the second input terminal, and a source follower having an input terminal coupled the second input terminal and an output terminal coupled the other terminal of the resistor.

### DESCRIPTION OF THE DRAWINGS

The invention will be more fully understood from the detailed description, given hereinbelow, and the accompanying drawings. The drawings and description are provided for purposes of illustration only and, thus, are not intended to limit the invention.

FIG. 1 is a circuit diagram of a conventional phase locked loop circuit.

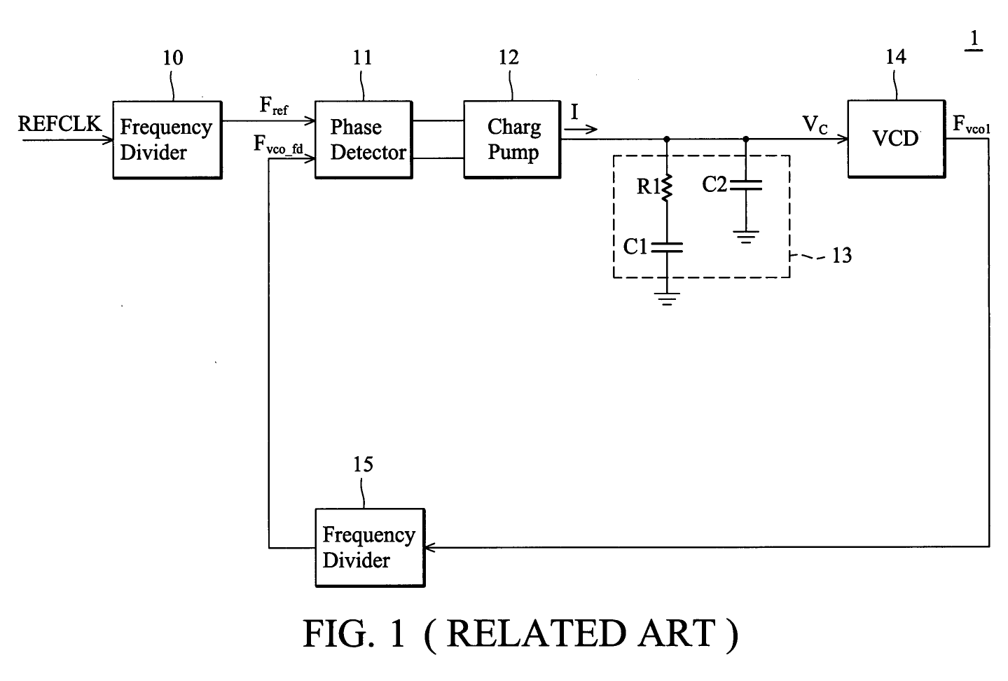

FIG. 2 is a circuit diagram of another conventional PLL circuit.

FIG. 3 is a circuit diagram of a PLL circuit according to an exemplary embodiment of the invention.

### DETAILED DESCRIPTION

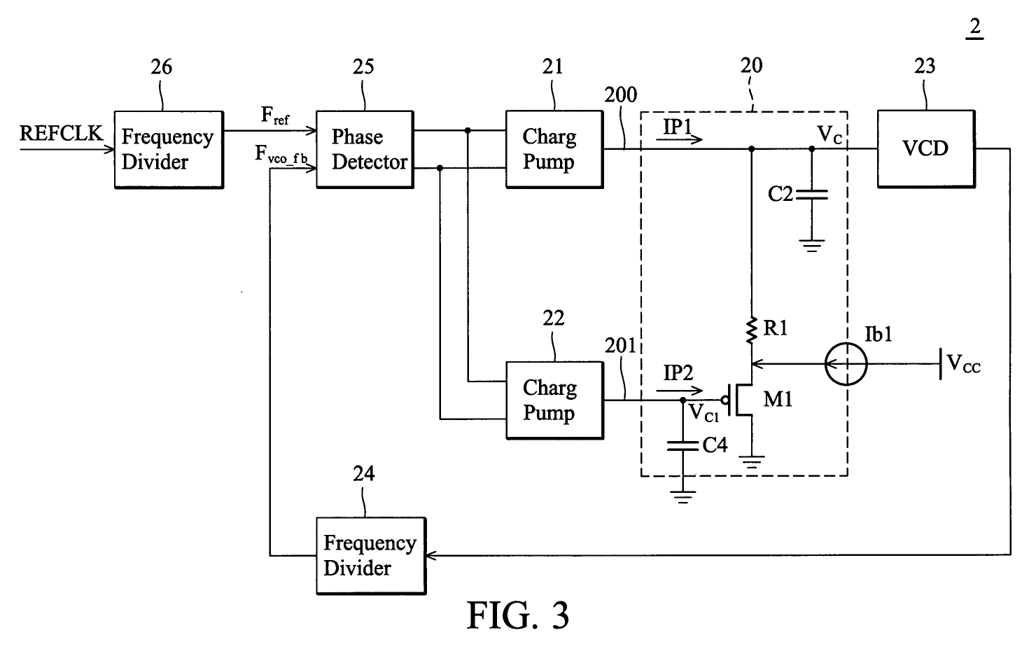

FIG. 3 is a circuit diagram of a PLL circuit according to an exemplary embodiment of the invention. In FIG. 3, the PLL circuit 3 comprises a loop filter 20, a first charge pump 21, a second charge pump 22, a voltage controlled oscillator (VCO) 23, a divider 24, a phase detector 25 and a divider 26.

The loop filter 20, having a first input terminal 200 and a second input terminal 201, comprises a first capacitor C2 coupled to the first input terminal 200, a resistor R1 with one terminal coupled to the first input terminal 200, a second capacitor C4 coupled to the second input terminal 201, a source follower M1 for example a PMOS or NMOS transistor, with a drain of the PMOS transistor coupled to a fixed voltage source (for example ground GND) and a gate of the PMOS transistor as an input terminal connected to the second input terminal 201 and a source of the PMOS transistor as an output terminal coupled to the other terminal of the resistor R1, and a current source Ib1 coupled to the output terminal of the source follower.

The first charge pump 21 is coupled to the first input terminal 200 and outputs a first current IP1. The second charge pump 22 is coupled to the second input terminal 201 and outputs a second current IP2. Current IP1 equals B times current IP2 (IP1=B×IP2 and B>1).

The voltage controlled oscillator 23 is coupled to the loop filter 20, receiving the filtered signal from the loop filter 20 and outputs a signal with a frequency corresponding to the voltage level (V_{C}) of the filtered signal.

The frequency divider 24 divides the frequency of the signal from the voltage controlled oscillator 23 by N and outputs a feedback signal.

The Phase detector 25 has two input terminals respectively coupled to output terminals of the frequency divider 24 and the other frequency divider 26, receiving a signal of frequency F_{ref} and the feedback signal of frequency F_{vco}_{_{—}}_{fb}. The Phase detector 25 also has two output terminals coupled to the first charge pump 21 and the second charge pump 22.

Based on the loop filter 20 and the condition of IP1=B×IP2, if the voltage gain of the source follower M1 is ideal value 1, then formula (1) and (2) are obtained as:

$$\begin{matrix}{V}_{C} = IP1 \times \frac{1}{\frac{1}{R1} + S \cdot C2} + {V}_{C1} \times \frac{\frac{1}{S \cdot C2}}{R1 + \frac{1}{S \cdot C2}} , \\ and & ( a ) \\ {V}_{C1} = \frac{IP2}{S \cdot C4} = \frac{IP1}{S \cdot B \cdot C4} . & ( b )\end{matrix}$$

Replacing V_{C1} in formula (a) with formula (b), transfer function (3) is obtained as:

$$\begin{matrix}\frac{{V}_{C}}{IP1} = \frac{R1 + \frac{1}{S \cdot B \cdot C4}}{1 + S \cdot R1 \cdot C2} \\ = \frac{R1 + \frac{1}{S \cdot B \cdot C4}}{1 + S \cdot R1 \cdot C2} \\ = \frac{\frac{R1}{S} \cdot ( S + \frac{1}{B \cdot R1 \cdot C4} )}{R1 \cdot C2 \cdot ( S + \frac{1}{R1 \cdot C2} )} \\ = \frac{S + \frac{1}{R1 \cdot B \cdot C4}}{S \cdot C2 \cdot ( S + \frac{1}{R1 \cdot C2} )} .\end{matrix} \qquad ( 3 )$$

From comparing the present transfer function (3) and the above described transfer function (1), the capacitance C1 corresponds to the capacitance C4, therefore B×C4=C1 and

$$C4 = \frac{C1}{B} .$$

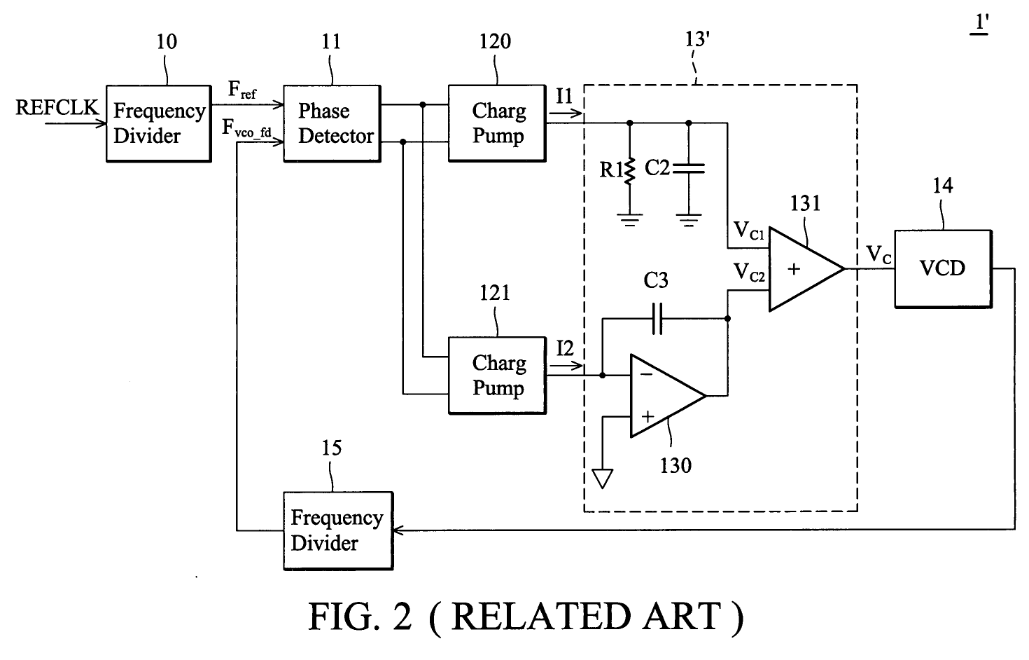

This means that the area of the capacitor C4 can be reduced to 1/B times that of the capacitor C1, according to this embodiment of the invention. In addition, the capacitor is a grounding capacitor and thus can be made using FET capacitors or MOS capacitors with higher capacitance per unit area. Furthermore, because only one source follower is used in this embodiment, the circuit noise is less than that of the configuration depicted in FIG. 2, and the disturbance due to phase noise and timing jitter can be reduced. The voltage V_{C1} is charged from a threshold voltage Vth, therefore accelerating the process in which the PLL circuit outputs a signal of required frequency.

While the invention has been described by way of examples and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A phase locked loop circuit comprising:
a loop filter having a first input terminal and a second input terminal and comprising:
a first capacitor coupled to the first terminal;
a resistor having one terminal coupled to the first input terminal;
a second capacitor coupled to the second input terminal; and
a source follower having an input terminal coupled to the second input terminal and an output terminal coupled the other terminal of the resistor;
a first charge pump coupled to the first input terminal outputting a first current; and
a second charge pump coupled to the second input terminal outputting a second current;
wherein the first current is a multiple of the second current.

2. The phase locked loop circuit as claimed in claim 1, further comprising a current source coupled to the output terminal of the source follower.

3. The phase locked loop circuit as claimed in claim 1, further comprising a voltage controlled oscillator coupled to the output terminal of the loop filter.

4. The phase locked loop circuit as claimed in claim 3, further comprising a first frequency divider coupled to the output terminal of the voltage controlled oscillator outputting a feedback signal.

5. The phase locked loop circuit as claimed in claim 5, further comprising a phase detector having two input terminals respectively coupled to the output terminal of the first frequency divider and a second frequency divider, and two output terminals respectively connected to the first charge pump and the second charge pump.

6. The phase locked loop circuit as claimed in claim 1, wherein the source follower comprises a drain connected to a fixed voltage source, a gate as the input terminal coupled to the output terminal of the second charge pump and a source connected to the other terminal of the resistor.
